(19) United States
(12) Patent Application Publication
(10) Pub. No.: US 2003/0146438 A1
(43) Pub. Date: Aug. 7, 2003

(54) Light emitting diode having a composite upper electrode

(76) Inventors: Chuan-Cheng Tu, Taipei (TW); Han-Tsung Lai, Hsin-Chuang City (TW); Liang-Jyi Yan, Hsin-Tien City (TW)

Correspondence Address: Jason Z. LIN, Supreme Patent Services, Post Office Box 2339, Saratoga, CA, 95070-0339, US

(21) Appl. No.: 10/273,715

(22) Filed: Oct. 18, 2002

(30) Foreign Application Priority Data
Feb. 1, 2002 (TW) 091101807

(51) Int. Cl. H01L 27/15

(52) U.S. Cl. 257/79

(57) ABSTRACT

A light emitting diode includes a lower electrode, a semiconductor substrate, a lower cladding layer, an action layer, an upper cladding layer, a window diffusion layer, and a composite upper electrode. The composite upper electrode includes an ohmic contact layer formed on a partial surface of the window diffusion layer, and a conductive transparent connecting oxidation layer coated on the ohmic contact layer and directly coated on a partial surface of the window diffusion layer to connect the ohmic contact layer and a wiring metal electrode layer.

### FIELD OF THE INVENTION

The present invention relates to a light emitting diode, and more particularly to a light emitting diode having a composite upper electrode.

### BACKGROUND OF THE INVENTION

A conventional light emitting diode in accordance with the prior art is disclosed in U.S. Pat. No. 5,789,768, and comprises a window diffusion layer (made of GaP) formed with an ohmic contact layer which may be made of a semiconductor material, such as GaAs, GaP, GaAsP or GaInP. In fact, only GaAs is available. However, GaAs will absorb the viewable light, so that it is not the optimum choice. In addition, the conductive transparent connecting oxidation layer covers the surface of the entire light emitting zone, so that the conductive transparent connecting oxidation layer will absorb the viewable light.

The Japanese Patent No. JP2001144323 disclosed a method for making the AlGaInP light emitting diode, wherein the surface layer of the light emitting diode is the AlGaInP layer, the ohmic contact layer has a spot-shape, the conductive transparent connecting oxidation layer covers the surface of the entire light emitting zone, and the uppermost layer is a wiring metal electrode layer. The width of the ohmic contact layer is smaller than 20 μm.

### SUMMARY OF THE INVENTION

The primary objective of the present invention is to provide a light emitting diode having a composite upper electrode, wherein the current barrier layer is mounted on the ohmic contact layer, so as to diffuse the current completely, thereby achieving the current diffusion effect, so as to enhance the illuminance of the light emitting diode.

Another objective of the present invention is to provide a light emitting diode having a composite upper electrode, wherein the current density of the unit area is reduced, thereby increasing the lifetime of the light emitting diode.

In accordance with the present invention, there is provided a light emitting diode having a composite upper electrode, comprising a lower electrode, a semiconductor substrate, a lower cladding layer, an action layer, an upper cladding layer, a window diffusion layer, and a composite upper electrode, wherein the composite upper electrode includes:

an ohmic contact layer, formed on a partial surface of the window diffusion layer;

a conductive transparent connecting oxidation layer, coated on the ohmic contact layer, and directly coated on a partial surface of the window diffusion layer, to connect the ohmic contact layer and a wiring metal electrode layer; and

the wiring metal electrode layer, being formed on a part of conductive transparent connecting oxidation layer, without overlapping the ohmic contact layer.

Preferably, the action layer is made of AlInGaP material.

Preferably, the action layer is made of a multiple quantum well (MQW) structure with AlInGaP material.

Preferably, the conductive transparent connecting oxidation layer is made of material which is chosen from the group consisting of ITO, InOₓ, ZnO and MgO.

Preferably, the semiconductor substrate is made of GaAs material.

Preferably, the lower cladding layer is made of AlInGaP material.

Preferably, the upper cladding layer is made of AlInGaP material.

Preferably, the wiring metal electrode layer is made of material which is chosen from the group consisting of Al metal, Ti/Al metal and Ti/Au metal.

Preferably, the light emitting diode having a composite upper electrode further comprises a coarse window diffusion layer for increasing the light emitting efficiency.

Preferably, the light emitting diode having a composite upper electrode further comprises a current barrier layer located under the wiring metal electrode layer between the conductive transparent connecting oxidation layer and the window diffusion layer.

Preferably, the current barrier layer is made of SiO₂ material.

Preferably, the light emitting diode having a composite upper electrode further comprises a first conductive type distributed bragg reflector (DBR) located between the substrate and the lower cladding layer.

Preferably, the first conductive type distributed bragg reflector is made of material which is chosen from the group consisting of (AlₓGa₍₁₋ₓ₎)_{y}In_{1-y}P (x is ranged between 0 and 1), and AlₓGa₍₁₋ₓ₎As (x is ranged between 0 and 1).

Preferably, the first conductive type distributed bragg reflector is made of material which is chosen from the group consisting of (AlₓGa₍₁₋ₓ₎)_{y}In_{1-y}P (x is ranged between 0 and 1), and AlₓGaAs (x is ranged between 0 and 1).

Preferably, the window diffusion layer is made of a compound semiconductor which is chosen from the group consisting of GaP compound semiconductor, GaAsP compound semiconductor, GaInP compound semiconductor, AlGaAs compound semiconductor, AlGaP compound semiconductor, and AlInGaP compound semiconductor.

Preferably, if the window diffusion layer is made of p-type semiconductor, the ohmic contact layer is made of material which is chosen from the group consisting of Be/Au material, Zn/Au material, In material, p-GaAs material, and p-InGaAs material.

Preferably, if the window diffusion layer is made of n-type semiconductor, the ohmic contact layer is made of material which is chosen from the group consisting of Ge/Au material, In material, n-GaAs material, and n-InGaAs material.

Preferably, the ohmic contact layer covers 2% to 75% of the surface area of the window diffusion layer.

Preferably, the conductive transparent connecting oxidation layer covers 5% to 99% of the surface area of the window diffusion layer.

Preferably, the action layer is made of AlGaAs material.

Preferably, the action layer is made of a multiple quantum well (MQW) structure with AlGaAs material.

Further benefits and advantages of the present invention will become apparent after a careful reading of the detailed description with appropriate reference to the accompanying drawings.

### BRIEF DESCRIPTION OF THE DRAWINGS

FIG. 1 is a schematic structural view of a light emitting diode having a composite upper electrode in accordance with a preferred embodiment of the present invention;

FIG. 2 is a schematic structural view of a light emitting diode having a composite upper electrode in accordance with another embodiment of the present invention;

FIG. 3 is a bottom plan view of a composite upper electrode of the light emitting diode in accordance with a preferred embodiment of the present invention;

FIG. 4 is a bottom plan view of a composite upper electrode of the light emitting diode in accordance with another embodiment of the present invention;

FIG. 5 shows the measured electrical features of the electrode made by a conventional process, and the electrode made by the composite electrode of the present invention; and

FIG. 6 shows the relationship between the light emitting current and the light emitting intensity of the composite electrode of the light emitting diode of the present invention and the conventional electrode of the conventional light emitting diode.

### DETAILED DESCRIPTION OF THE INVENTION

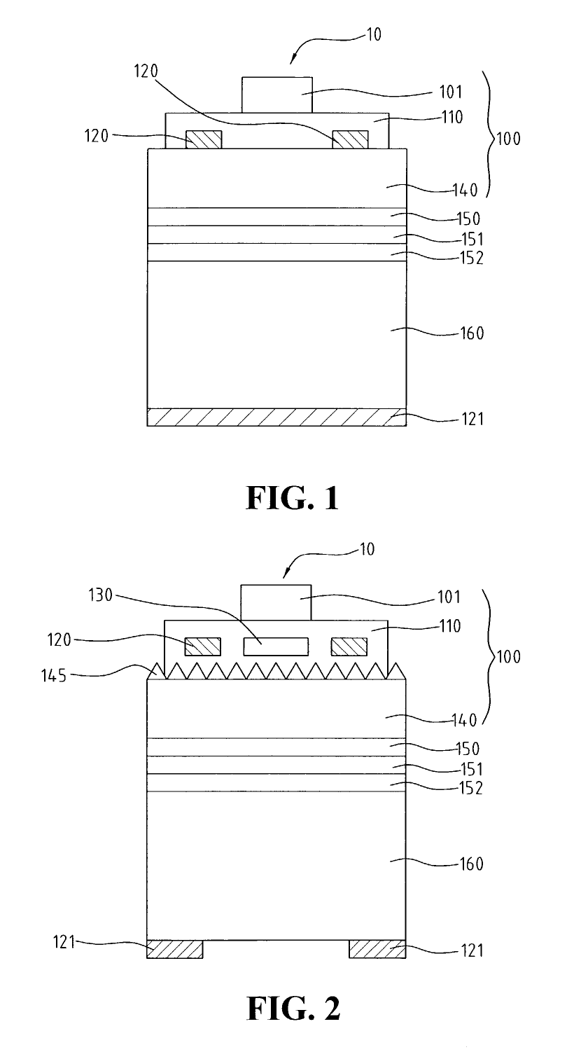

Referring to the drawings and initially to FIG. 1, a light emitting diode 10 having a composite upper electrode in accordance with a preferred embodiment of the present invention comprises a substrate 160 made of GaAs, a lower electrode 121 mounted on the bottom of the substrate 160. The light emitting diode 10 has a window diffusion layer 140 which is pre-fabricated with an ohmic contact layer 120. The ohmic contact layer 120 is formed on a partial surface of the window diffusion layer 140. The window diffusion layer 140 is made of a compound semiconductor, such as GaP compound semiconductor, GaAsP compound semiconductor, GaInP compound semiconductor, AlGaAs compound semiconductor, AlGaP compound semiconductor, or AlInGaP compound semiconductor.

The ohmic contact layer 120 is formed on a partial surface of the window diffusion layer 140. Thus, if the ohmic contact layer 120 is made of material, such Be/Au material, Zn/Au material, In material, p-GaAs material, or p-InGaAs material, the window diffusion layer 140 is made of p-type semiconductor, such as p-GaP. On the contrary, if the ohmic contact layer 120 is made of material, such Ge/Au material, In material, n-GaAs material, or n-InGaAs material, the window diffusion layer 140 is made of n-type semiconductor, such as n-GaP.

In addition, if the window diffusion layer 140 is made of n-InxGaP material, wherein 0.2<x<0.3, the ohmic contact layer 120 is made of material, such Ge/Au material, In material, n-GaAs material, or n-InGaAs material. It is appreciated that, the ohmic contact layer 120 may have an annular shape, a spot-shape, or other shape.

Then, a conductive transparent connecting oxidation layer 110 is plated or coated on the ohmic contact layer 120, and is directly coated on a partial surface of the window diffusion layer 140. The conductive transparent connecting oxidation layer 110 is partially coated on the window diffusion layer 140 for enhancing the light emitting efficiency of the light emitting diode. The area of the conductive transparent connecting oxidation layer 110 may be shortened efficiently, thereby reducing the light absorption of the conductive transparent connecting oxidation layer 110, without affecting the function of connecting the diffusion current.

The conductive transparent connecting oxidation layer 110 may be made of material, such as ITO, InOₓ, ZnO, or MgO. The conductive transparent connecting oxidation layer 110 may be a complete layer or a figure. The conductive transparent connecting oxidation layer 110 may be used to connect a wiring metal electrode layer 101 and the ohmic contact layer 120. The wiring metal electrode layer 101 may be made of material, such as Al metal, Ti/Al metal or Ti/Au metal.

The light emitting diode 10 comprises a composite upper electrode 100 which includes the ohmic contact layer 120, the conductive transparent connecting oxidation layer 110, and the wiring metal electrode layer 101. The current is introduced from the wiring metal electrode layer 101 through the conductive transparent connecting oxidation layer 110 and the ohmic contact layer 120, and is finally conveyed into the window diffusion layer 140 of the light emitting diode 10.

Referring to FIG. 2, the light emitting diode 10 is provided with a current barrier layer 130, and a coarse window diffusion layer 145. The bottom of the light emitting diode 10 is provided with lower electrodes 121. The coarse window diffusion layer 145 may be made of material, such as GaP, for increasing the current diffusion to have an even distribution effect. Before the current reaches the action layer 151, when the current is distributed more evenly, the electrical feature of the light emitting diode 10 is better. In addition, the coarse window diffusion layer 145 may reduce the full reflective angle, thereby increasing the external quantum effect and increasing the final illuminance.

The coarse window diffusion layer 145 may be made by using a doping metal layer. In the p-type semiconductor, BeAu or ZnAu is plated on GaP, to form an alloy at 420° C. Then, the doping metal layer is removed by etching, thereby obtaining the coarse window diffusion layer 145.

The contact between the coarse window diffusion layer 145, the ohmic contact layer 120, the conductive transparent connecting oxidation layer 110 and the wiring metal electrode layer 101 has to be an ohmic contact.

The current barrier layer 130 is located under the wiring metal electrode layer 101 between the conductive transparent connecting oxidation layer 110 and the window diffusion layer 140. The current barrier layer 130 may be made of material, such as SiO₂ or SiNₓ. The current barrier layer 130 is mounted on the ohmic contact layer 120, so as to diffuse the current completely, thereby achieving the current diffusion effect. Provision of the current barrier layer 130 is not necessary. The current barrier layer 130 is made of SiO₂. The ohmic contact layer 120 is mounted between the coarse window diffusion layer 145 and the conductive transparent connecting oxidation layer 110, for increasing the bonding effect therebetween.

The action layer 151 of the light emitting diode 10 is made of material, such as AlInGaP or multiple quantum well (MQW) with AlInGaP. The action layer 151 of the light emitting diode 10 may convert the electrical energy into an optical energy and a little heat energy, thereby emitting the light.

For increasing the light emitting efficiency, the light emitting diode 10 further comprises a first conductive type distributed bragg reflector (DBR) located between the substrate 160 and the lower cladding layer 152 of the light emitting diode 10. The first conductive type distributed bragg reflector of the light emitting diode 10 is made of material, such as AlInGaP or AlGaAs.

As mentioned in the present invention, the light emitting diode 10 comprises a lower electrode 121, a semiconductor substrate 160, a lower cladding layer 152, an action layer 151, an upper cladding layer 150, a window diffusion layer 140, and a composite upper electrode 100. The composite upper electrode 100 includes an ohmic contact layer 120, a conductive transparent connecting oxidation layer 110, and a wiring metal electrode layer 101.

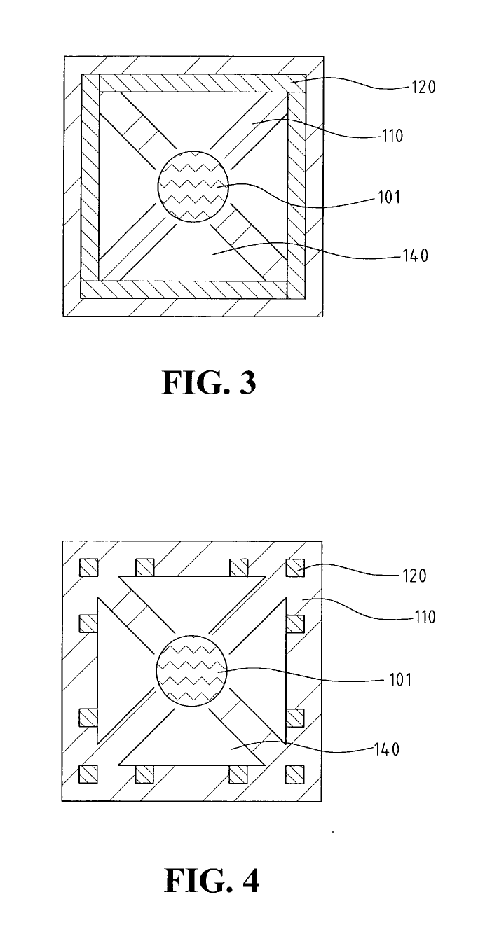

Referring to FIG. 3, the current flows into the light emitting diode 10 from the wiring metal electrode layer 101, then achieves the current distribution in the conductive transparent connecting oxidation layer 110, and then reaches the ohmic contact layer 120, wherein the blank part is the window diffusion layer 140. In the figure, the ohmic contact layer 120 has an annular shape.

Referring to FIG. 4, the current flows into the light emitting diode 10 from the wiring metal electrode layer 101, then achieves the current diffusion in the conductive transparent connecting oxidation layer 110, and then reaches the ohmic contact layer 120, wherein the blank part is the window diffusion layer 140. In the figure, the ohmic contact layer 120 has a spot-shape.

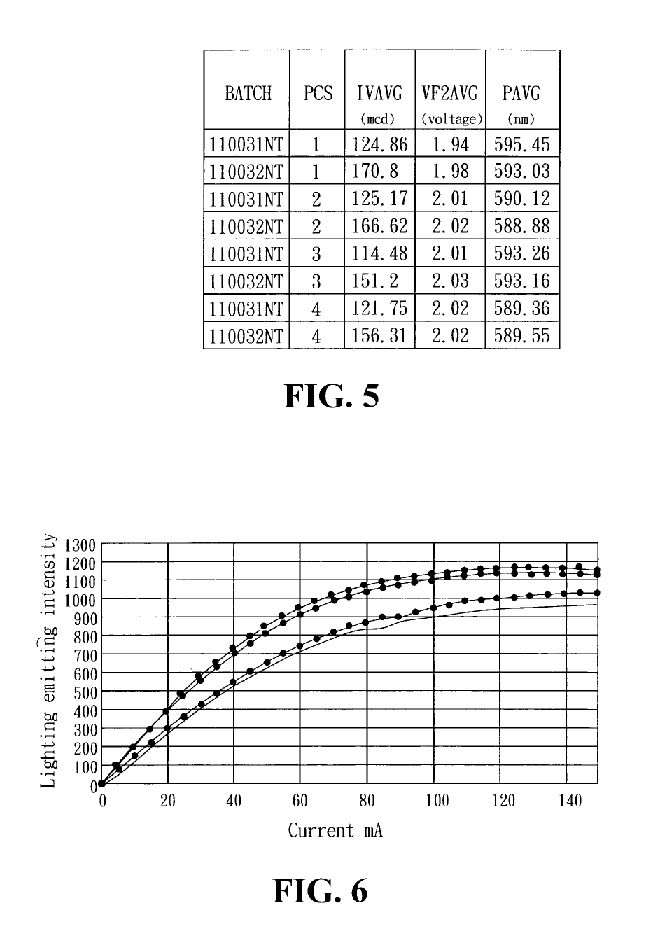

Referring to FIG. 5, the 110031NT batch and the 110032NT batch are formed by breaking the same epitaxy chip. The electrode of the 110031NT batch is made by a conventional process, and the electrode of the 110032NT batch is made of the composite electrode of the present invention. FIG. 5 shows the measured electrical features of the electrode of the 110031NT batch that is made by a conventional process, and the electrode of the 110032NT batch that is made of the composite electrode of the present invention. Thus, the average illuminance may be increased by 30%.

FIG. 6 shows the relationship between the light emitting current and the light emitting intensity of the composite electrode of the light emitting diode of the present invention and the conventional electrode of the conventional light emitting diode. The light emitting intensity has not been calibrated by the wavelength, so that the light emitting intensity is not an absolute value. As shown in FIG. 6, under the high current, the illuminance of the composite electrode of the light emitting diode of the present invention may be increased by 20% in comparison with the conventional electrode of the conventional light emitting diode.

Although the invention has been explained in relation to its preferred embodiment as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A light emitting diode having a composite upper electrode, comprising a lower electrode, a semiconductor substrate, a lower cladding layer, an action layer, an upper cladding layer, a window diffusion layer, and a composite upper electrode, wherein the composite upper electrode includes:
an ohmic contact layer, formed on a partial surface of the window diffusion layer;
a conductive transparent connecting oxidation layer, coated on the ohmic contact layer, and directly coated on a partial surface of the window diffusion layer, to connect the ohmic contact layer and a wiring metal electrode layer; and
the wiring metal electrode layer, being formed on a part of conductive transparent connecting oxidation layer, without overlapping the ohmic contact layer.

2. The light emitting diode having a composite upper electrode in accordance with claim 1, wherein the action layer is made of AlInGaP material.

3. The light emitting diode having a composite upper electrode in accordance with claim 1, wherein the action layer is made of a multiple quantum well (MQW) structure with AlInGaP material.

4. The light emitting diode having a composite upper electrode in accordance with claim 1, wherein the conductive transparent connecting oxidation layer is made of material which is chosen from the group consisting of ITO, InOₓ, ZnO and MgO.

5. The light emitting diode having a composite upper electrode in accordance with claim 1, wherein the semiconductor substrate is made of GaAs material.

6. The light emitting diode having a composite upper electrode in accordance with claim 1, wherein the lower cladding layer is made of AlInGaP material.

7. The light emitting diode having a composite upper electrode in accordance with claim 1, wherein the upper cladding layer is made of AlInGaP material.

8. The light emitting diode having a composite upper electrode in accordance with claim 1, wherein the wiring metal electrode layer is made of material which is chosen from the group consisting of Al metal, Ti/Al metal and Ti/Au metal.

9. The light emitting diode having a composite upper electrode in accordance with claim 1, further comprising a coarse window diffusion layer for increasing the light emitting efficiency.

10. The light emitting diode having a composite upper electrode in accordance with claim 1, further comprising a current barrier layer located under the wiring metal electrode layer between the conductive transparent connecting oxidation layer and the window diffusion layer.

11. The light emitting diode having a composite upper electrode in accordance with claim 10, wherein the current barrier layer is made of SiO₂ material.

12. The light emitting diode having a composite upper electrode in accordance with claim 1, further comprising a first conductive type distributed bragg reflector (DBR) located between the substrate and the lower cladding layer.

13. The light emitting diode having a composite upper electrode in accordance with claim 12, wherein the first conductive type distributed bragg reflector is made of material which is chosen from the group consisting of (AlₓGa₍₁₋ₓ₎)_{y}In_{1-y}P (x is ranged between 0 and 1), and AlₓGa₍₁₋ₓ₎As (x is ranged between 0 and 1).

14. The light emitting diode having a composite upper electrode in accordance with claim 1, wherein the first conductive type distributed bragg reflector is made of material which is chosen from the group consisting of (AlₓGa₍₁₋ₓ₎)_{y}In_{1-y}P (x is ranged between 0 and 1), and AlₓGaAs (x is ranged between 0 and 1).

15. The light emitting diode having a composite upper electrode in accordance with claim 1, wherein the window diffusion layer is made of a compound semiconductor which is chosen from the group consisting of GaP compound semiconductor, GaAsP compound semiconductor, GaInP compound semiconductor, AlGaAs compound semiconductor, AlGaP compound semiconductor, and AlInGaP compound semiconductor.

16. The light emitting diode having a composite upper electrode in accordance with claim 1, wherein if the window diffusion layer is made of p-type semiconductor, the ohmic contact layer is made of material which is chosen from the group consisting of Be/Au material, Zn/Au material, In material, p-GaAs material, and p-InGaAs material.

17. The light emitting diode having a composite upper electrode in accordance with claim 1, wherein if the window diffusion layer is made of n-type semiconductor, the ohmic contact layer is made of material which is chosen from the group consisting of Ge/Au material, In material, n-GaAs material, and n-InGaAs material.

18. The light emitting diode having a composite upper electrode in accordance with claim 1, wherein the ohmic contact layer covers 2% to 75% of the surface area of the window diffusion layer.

19. The light emitting diode having a composite upper electrode in accordance with claim 1, wherein the conductive transparent connecting oxidation layer covers 5% to 99% of the surface area of the window diffusion layer.

20. The light emitting diode having a composite upper electrode in accordance with claim 1, wherein the action layer is made of AlGaAs material.

21. The light emitting diode having a composite upper electrode in accordance with claim 1, wherein the action layer is made of a multiple quantum well (MQW) structure with AlGaAs material.
